(19) United States
(12) Patent Application Publication
(10) Pub. No.: US 2026/0231788 A1
(43) Pub. Date: Aug. 6, 2026

(54) LEAD FRAME STRIP HAVING MOLDING BUSES AND METHOD OF USING THE SAME TO FABRICATE SEMICONDUCTOR PACKAGES

(71) Applicant: ALPHA AND OMEGA SEMICONDUCTOR INTERNATIONAL LP, TORONTO (CA)

(72) Inventors: Yan Xun Xue, Los Gatos, CA (US); Madhur Bobde, Sunnyvale, CA (US); Long-Ching Wang, Cupertino, CA (US)

(73) Assignee: ALPHA AND OMEGA SEMICONDUCTOR INTERNATIONAL LP, TORONTO, ON (CA)

(21) Appl. No.: 19/043,099

(22) Filed: Jan. 31, 2025

(51) Int. Cl. H01L 23/495; H01L 21/48; H01L 21/56; H01L 23/00; H01L 23/31; H01L 25/07; H10D 80/20

(52) U.S. Cl. CPC H10W 70/481; H10D 80/251; H10W 70/048; H10W 70/411; H10W 74/014; H10W 74/016; H10W 74/114; H10W 90/00; H10W 72/0198; H10W 90/756; H10W 90/766

(57) ABSTRACT

A lead frame strip comprises a plurality of blocks. Each block of the plurality of blocks comprises a molding bus, a first plurality of rows, a first plurality of molding gates, a second plurality of rows, and a second plurality of molding gates. The first plurality of rows are on a first side of the molding bus. The second plurality of rows are on a second side of the molding bus. The second side is opposite to the first side. A method comprises the steps of providing a lead frame strip; mounting a plurality of transistors; attaching a plurality of metal clips or a plurality of bond wires; forming a molding encapsulation; applying a punching process; and applying a sawing process.

### FIELD OF THE INVENTION

This invention relates generally to a lead frame strip and a method of using the same. More particularly, the present invention relates to a lead frame strip having molding buses in between lead frame blocks.

### BACKGROUND OF THE INVENTION

U.S. Pat. No. 7,943,424 to Wang et al., US Patent Application Publication No. 2011/0129962 to Wang et al., and US Patent Application Publication No. 2015/0325503 to Lim et al. discloses a manufacturing method including a punching process followed by a sawing process.

The present disclosure discloses a lead frame strip having molding buses in between lead frame blocks. A molding encapsulation process is followed by a punching process, and then followed by a sawing process. The advantages of the punching process include shorter process time, better wettable leads, and easier to pick up packages during an assembling step. The advantages of the sawing process include compact semiconductor packages (space saving for a higher lead frame density in a lead frame strip), flexible semiconductor package size, and no protruded tie bars from the molding encapsulation of the semiconductor packages.

### SUMMARY OF THE INVENTION

A lead frame strip comprises a plurality of blocks. Each block of the plurality of blocks comprises a molding bus, a first plurality of rows, a first plurality of molding gates, a second plurality of rows, and a second plurality of molding gates. The first plurality of rows are on a first side of the molding bus. The second plurality of rows are on a second side of the molding bus. The second side is opposite to the first side.

A method for fabricating a semiconductor package is also disclosed. The method comprises the steps of providing a lead frame strip; mounting a plurality of transistors; attaching a plurality of metal clips or a plurality of bond wires; forming a molding encapsulation; applying a punching process; and applying a sawing process.

### BRIEF DESCRIPTION OF THE DRAWINGS

FIG. 1 is a front view of a lead frame strip in examples of the present disclosure.

FIG. 2 is a flowchart of a process to develop a semiconductor package in examples of the present disclosure.

FIGS. 3A, 3B 3D, 3EA, 3EB, 3FA, and 3FB are front views and FIG. 3CA and 3CA are side views showing the steps of the process to fabricate a semiconductor package in examples of the present disclosure.

FIG. 4A is a perspective top view and FIG. 4B is a perspective bottom view of a semiconductor package in examples of the present disclosure.

### DETAILED DESCRIPTION OF THE INVENTION

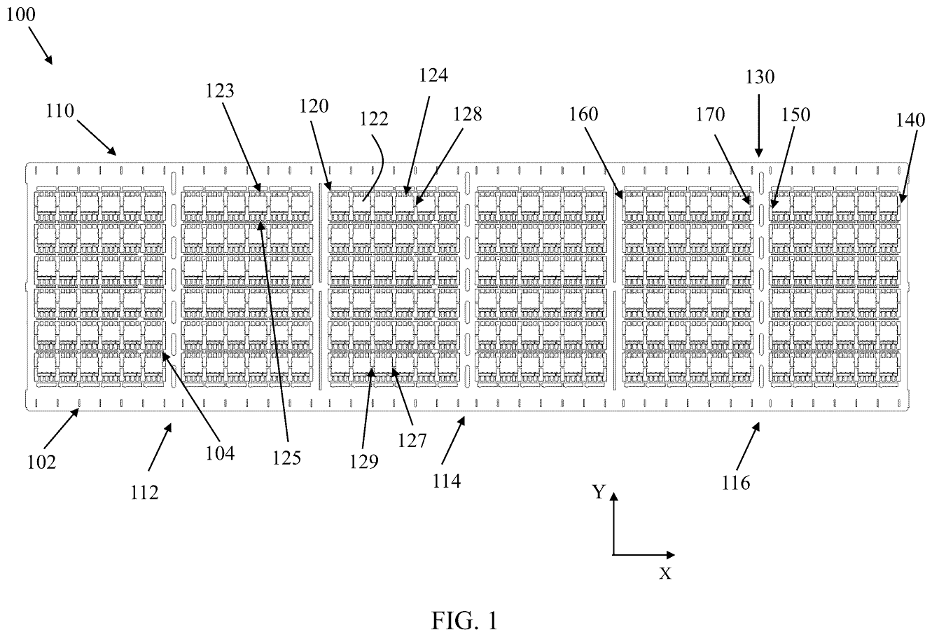

FIG. 1 is a front view of a lead frame strip 100 in examples of the present disclosure. The lead frame strip 100 comprises a plurality of blocks 110. Though only three blocks 112, 114, and 116 of the plurality of blocks 110 are shown in FIG. 1, a number of blocks contained in a lead frame strip 100 may vary. Each block of the plurality of blocks 110 comprises a molding bus 130, a first plurality of rows 140, a first plurality of molding gates 150, a second plurality of rows 160, and a second plurality of molding gates 170. The molding bus 130 extends along a first direction (Y direction). The first plurality of rows 140 extend along a second direction (X direction) perpendicular to the first direction (Y direction). The first plurality of rows 140 are on a first side (for example, right-hand side) of the molding bus 130. The first plurality of molding gates 150 connect the molding bus 130 to the first plurality of rows 140. The second plurality of rows 160 extend along the second direction (X direction). The second plurality of rows 160 are on a second side (for example, left-hand side) of the molding bus 130. The second side (for example, left-hand side) is opposite to the first side (for example, right-hand side) of the molding bus 130. The second plurality of molding gates 170 connect the molding bus 130 to the second plurality of rows 160.

Each row of the first plurality of rows 140 and the second plurality of rows 160 comprises a plurality of lead frames 120. Though FIG. 1 shows six lead frames of the plurality of lead frames 120 are contained in each row of the first plurality of rows 140 and the second plurality of rows 160, a number of lead frames contained in a row may vary.

Each lead frame of the plurality of lead frames 120 comprises a die paddle 122, a plurality of leads 124, and a plurality of tie bars 128. The plurality of leads 124 connect to the lead frames 120. A number of leads connected to the lead frames 120 may vary. The plurality of leads extending along the first direction (Y direction). The plurality of tie bars 128 connect to the die paddle 122. A number of tie bars connected to the die paddle 122 may vary. The plurality of tie bars 128 extend along the second direction (X direction). The molding bus 130 provides a channel for the injection of molding material to flow to the first plurality of molding gates 150 and the second plurality of molding gates 170 to fill the molding chamber for each row of lead frames of the first plurality of rows 340 and the second plurality of rows 160.

In examples of the present disclosure, the first plurality of rows 140 and the second plurality of rows 160 are symmetric with respect to the molding bus 130.

In examples of the present disclosure, the lead frame strip 100 further comprises a plurality of sawing marks 102 at a periphery edge of the lead frame strip 100 distributed along the second direction (X direction). Each of the plurality of sawing marks 102 extends along the first direction (Y direction) aligned to a center of interconnection between adjacent lead frames or between a lead frame and adjacent molding bus or a block periphery edge.

In examples of the present disclosure, the lead frame strip 100 further comprises a plurality of punching marks 104 disposed between adjacent rows and extending along the second direction (X direction).

The plurality of leads 124 comprises one or more upper leads 123 connected to the die paddle 122 and one or more lower leads 125 separated from the die paddle 122. The one or more upper leads 123 and the one or more lower leads 125 are symmetric with respective to a center of the die paddle 122.

The plurality of tie bars 128 comprises a first tie bar 127 and a second tie bar 129. The first tie bar 127 and the second tie bar 129 are symmetric with respective to a center of the die paddle 122.

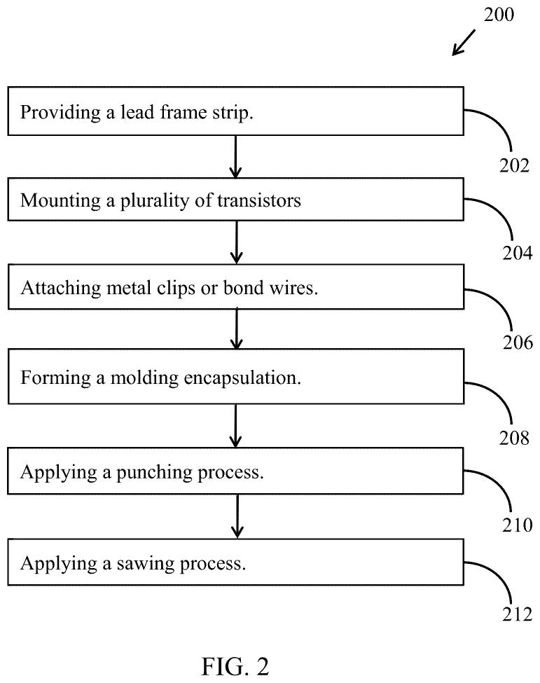

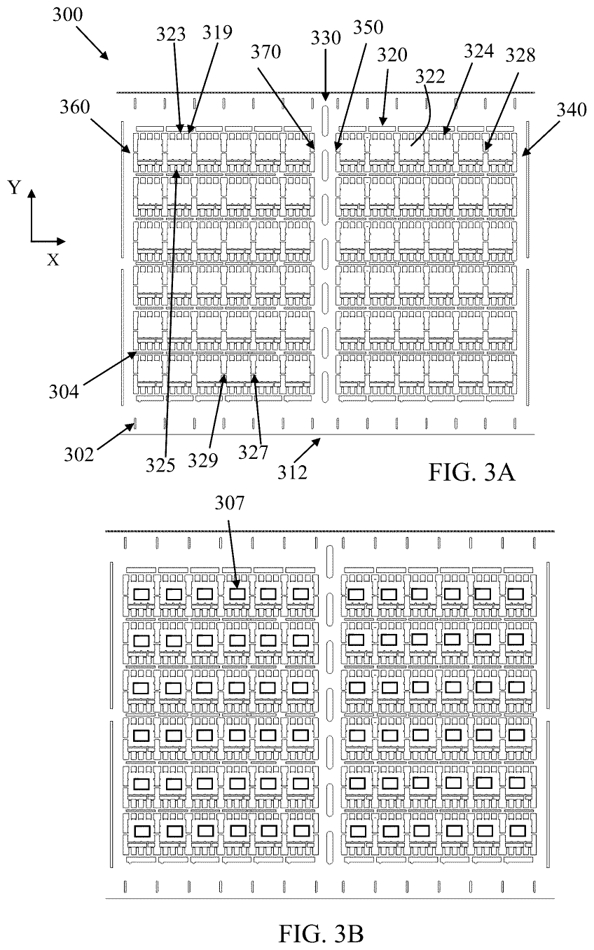

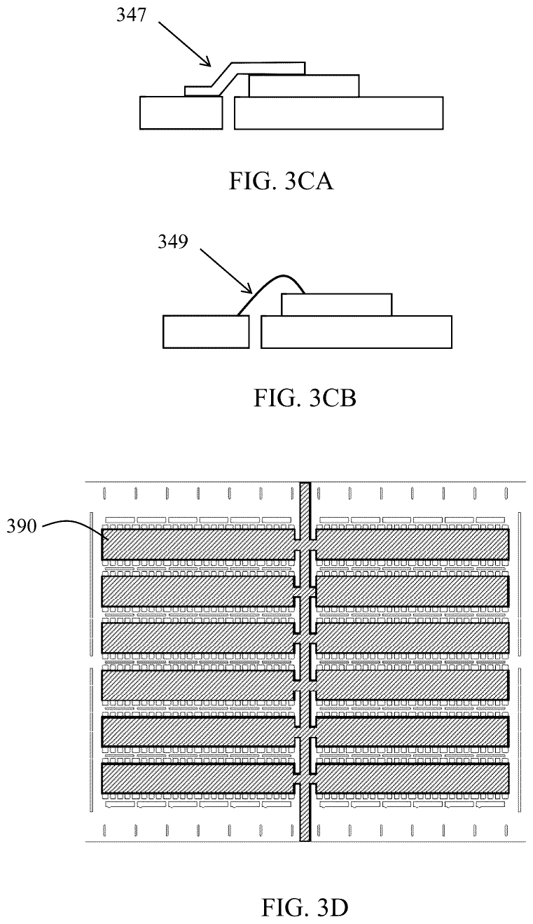

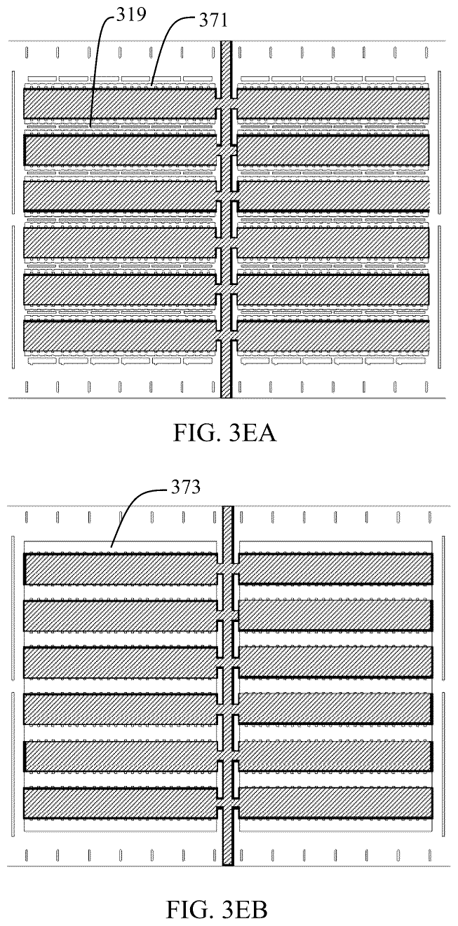

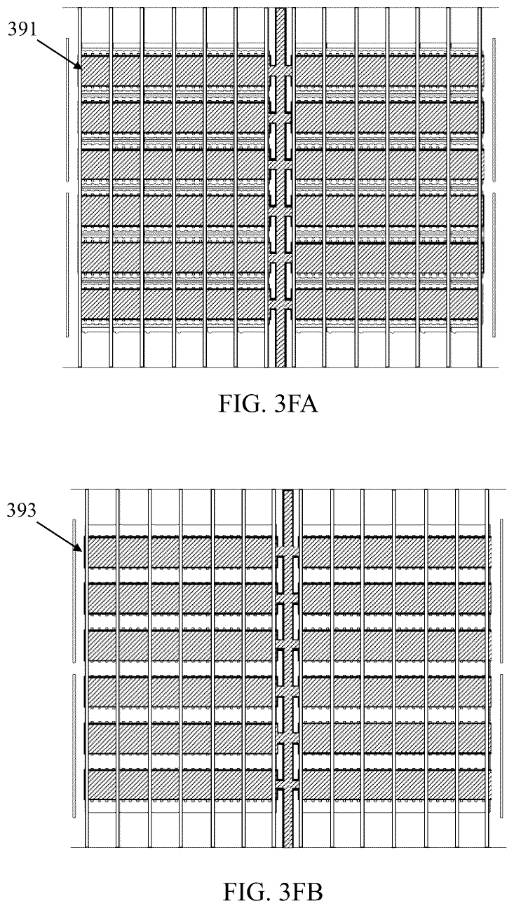

FIG. 2 is a flowchart of a process 200 to develop a semiconductor package in examples of the present disclosure. FIGS. 3A, 3B 3D, 3EA, 3EB, 3FA, and 3FB are front views and FIG. 3CA and 3CA are side views showing the steps of the process 200 to fabricate a semiconductor package in examples of the present disclosure. For simplicity, only one block is shown in FIGS. 3A, 3B 3D, 3EA, 3EB, 3FA, and 3FB. A number of blocks in a lead frame strip may vary. For simplicity, only one semiconductor package is shown in FIG. 3CA and 3CA. A number of semiconductor packages fabricated from a block may vary. The process 200 may start from block 202.

In block 202, referring now to FIG. 3A, a lead frame strip 300 is provided. The lead frame strip 300 comprises a plurality of blocks 110 of FIG. 1. For simplicity, only one block 312 is shown in FIG. 3A. Each block of the plurality of blocks 110 of FIG. 1 comprises a molding bus 330, a first plurality of rows 340, a first plurality of molding gates 350, a second plurality of rows 360, and a second plurality of molding gates 370. The molding bus 330 extends along a first direction (Y direction). The first plurality of rows 340 extend along a second direction (X direction) perpendicular to the first direction (Y direction). The first plurality of rows 340 are on a first side (for example, right-hand side) of the molding bus 330. The first plurality of molding gates 350 connect the molding bus 330 to the first plurality of rows 340. The second plurality of rows 360 extend along the second direction (X direction). The second plurality of rows 360 are on a second side (for example, left-hand side) of the molding bus 330. The second side (for example, left-hand side) is opposite to the first side (for example, right-hand side) of the molding bus 330. The second plurality of molding gates 370 connect the molding bus 330 to the second plurality of rows 360.

Each row of the first plurality of rows 340 and the second plurality of rows 360 comprises a plurality of lead frames 320. Though FIG. 3A shows six lead frames of the plurality of lead frames 320 are contained in each row of the first plurality of rows 340 and the second plurality of rows 360, a number of lead frames contained in a row may vary.

Each lead frame of the plurality of lead frames 320 comprises a die paddle 322, a plurality of leads 324, and a plurality of tie bars 328. A number of leads connected to the die paddle 322 may vary. The plurality of leads extending along the first direction (Y direction). The plurality of tie bars 328 connect to the die paddle 322. A number of tie bars connected to the die paddle 322 may vary. The plurality of tie bars 328 extend along the second direction (X direction).

In examples of the present disclosure, the first plurality of rows 340 and the second plurality of rows 360 are symmetric with respect to the molding bus 330.

In examples of the present disclosure, the lead frame strip 300 further comprises a plurality of sawing marks 302 extending along the first direction (Y direction).

In examples of the present disclosure, the lead frame strip 300 further comprises a plurality of punching marks 304 extending along the second direction (X direction).

The plurality of leads 324 comprises one or more upper leads 323 connected to the die paddle 322 and one or more lower leads 325 separated from the die paddle 322. The one or more upper leads 323 and the one or more lower leads 325 are symmetric with respective to a center of the die paddle 322.

The plurality of tie bars 328 comprises a first tie bar 327 and a second tie bar 329. The first tie bar 327 and the second tie bar 329 are symmetric with respective to a center of the die paddle 322. Block 202 may be followed by block 204.

In block 204, referring now to FIG. 3B, a plurality of transistors 307 are mounted. In examples of the present disclosure, the plurality of transistors 307 are metal-oxide-silicon field-effect transistors (MOSFETs). In example of the present disclosure, each transistor of the plurality of transistors 307 is of a rectangular prism shape. Block 204 may be followed by block 206.

In block 206, referring now to FIG. 3CA and 3CB, a plurality of metal clips 347 or a plurality of bond wires 349 are attached. In one example, a semiconductor package contains the plurality of metal clips 347 only (excluding the plurality of bond wires 349). In another example, a semiconductor package contains the plurality of bond wires 349 only (excluding the plurality of metal clips 347). In still another example, a semiconductor package contains both the plurality of metal clips 347 and the plurality of bond wires 349. Block 206 may be followed by block 208.

In block 208, referring now to FIG. 3D, a molding encapsulation 390 is formed. The molding encapsulation 380 encloses plurality of transistors 307, the plurality of metal clips 347 or the plurality of bond wires 349, and a majority portion of the lead frame strip 300. A majority portion refers to larger than 50%. The molding material flows from the molding bus 330 of FIG. 3A, through the first plurality of molding gates 350, to the first plurality of rows 340. The molding material flows from the molding bus 330 of FIG. 3A, through the second plurality of molding gates 370, to the second plurality of rows 360. Block 208 may be followed by block 210.

In block 210, referring now to FIG. 3EA and 3EB, a punching process is applied by referencing the plurality of punching marks 304. In the example of FIG. 3A, a respective portion of each lead of the plurality of leads 324 are removed. In the example of FIG. 3B, the plurality of metal sections 319 of FIG. 3A (between the plurality of leads 324) and a respective portion of each lead of the plurality of leads 324 are removed. A punched cavity 371 of FIG. 3EA is smaller than a punched cavity 373 of FIG. 3EB so that the structure of FIG. 3EA provides better support for subsequent process steps. Block 210 may be followed by block 212.

In block 212, referring now to FIG. 3FA and 3FB, a sawing process is applied referencing the plurality of sawing marks 302. A plurality of semiconductor packages 391 of FIG. 3FA are separated from one another. A plurality of semiconductor packages 393 of FIG. 3FB are separated from one another.

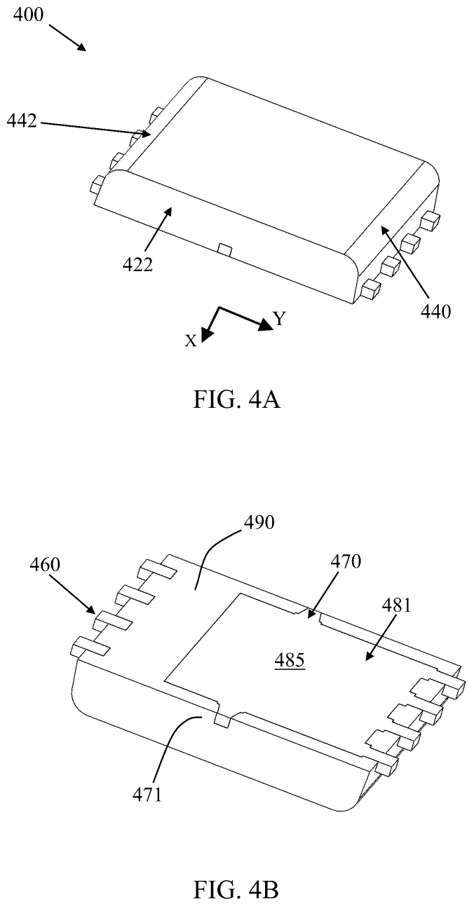

FIG. 4A is a perspective top view and FIG. 4B is a perspective bottom view of a semiconductor package 400, fabricated by the process 200, in examples of the present disclosure. A top of the semiconductor package 400 comprises a first straight edge 420, a second straight edge 422, a first filleted edge 440, and a second filleted edge 442. The first filleted edge 440 and the second filleted edge 442 are created by the punching process (to form leads by not changing the molding encapsulation) of block 210. The first straight edge 420 and the second straight edge 422 are created by the sawing process of block 212. The advantages of the punching process of block 210 include shorter process time, better wettable leads 460 (a respective rectangular prism portion of each lead of the plurality of leads 460 is exposed from the molding encapsulation 490, that is, protrusion out of the molding encapsulation 490), and easier to pick up semiconductor packages during an assembling step (because of the first filleted edge 440 and the second filleted edge 442). The advantages of the sawing process of block 212 include compact semiconductor packages (space saving for a higher lead frame density in a lead frame strip), flexible semiconductor package size, and no protruded tie bars 470 from the molding encapsulation 490 of the semiconductor packages.

The first straight edge 420 extends along the first direction (Y direction). The second straight edge 422 extends along the first direction (Y direction). The second straight edge 422 is opposite the first straight edge 420. The first filleted edge 440 extends along the second direction (X direction). The second filleted edge 442 extends along the second direction (X direction). The second filleted edge 442 is opposite the first filleted edge 440.

The molding encapsulation 490 encloses a respectively shortened portion of each tie bar of the plurality of tie bars except that a respective sawed surface 471 of each tie bar of the plurality of tie bars 470 is exposed form the molding encapsulation 490.

In examples of the present disclosure, a bottom surface 485 of the lead frame 481 is exposed from the molding encapsulation 490.

Those of ordinary skill in the art may recognize that modifications of the embodiments disclosed herein are possible. For example, a number of blocks contained in a lead frame strip 100 may vary. Other modifications may occur to those of ordinary skill in this art, and all such modifications are deemed to fall within the purview of the present invention, as defined by the claims.

1. A lead frame strip comprising:
a plurality of blocks, each block of the plurality of blocks comprising:
a molding bus extending along a first direction;
a first plurality of rows extending along a second direction perpendicular to the first direction, the first plurality of rows being on a first side of the molding bus;
a first plurality of molding gates connecting the molding bus to the first plurality of rows;
a second plurality of rows extending along the second direction, the second plurality of rows being on a second side of the molding bus opposite the first side of the molding bus; and
a second plurality of molding gates connecting the molding bus to the second plurality of rows;
each row of the first plurality of rows and the second plurality of rows comprising:
a plurality of lead frames, each lead frame of the plurality of lead frames comprising:
a die paddle;
a plurality of leads extending along the first direction; and
a plurality of tie bars connecting to the die paddle, the plurality of tie bars extending along the second direction.

2. The lead frame strip of claim 1, wherein the first plurality of rows and the second plurality of rows are symmetric with respect to the molding bus.

3. The lead frame strip of claim 1 further comprising a plurality of sawing marks extending along the first direction.

4. The lead frame strip of claim 1 further comprising a plurality of punching marks extending along the second direction.

5. The lead frame strip of claim 1, wherein the plurality of leads comprises:
one or more upper leads connected to the die paddle; and
one or more lower leads separated from the die paddle;
wherein the one or more upper leads and the one or more lower leads are symmetric with respective to a center of the die paddle.

6. The lead frame strip of claim 1, wherein the plurality of tie bars comprises:
a first tie bar; and
a second tie bar;
wherein the first tie bar and the second tie bar are symmetric with respective to a center of the die paddle.

7. A method for fabricating a semiconductor package, the method comprising the steps of:
providing a lead frame strip comprising:
a plurality of blocks, each block of the plurality of blocks comprising:
a molding bus extending along a first direction;
a first plurality of rows extending along a second direction perpendicular to the first direction, the first plurality of rows being on a first side of the molding bus;
a first plurality of molding gates connecting the molding bus to the first plurality of rows;
a second plurality of rows extending along the second direction, the second plurality of rows being on a second side of the molding bus opposite the first side of the molding bus; and
a second plurality of molding gates connecting the molding bus to the second plurality of rows;
each row of the first plurality of rows and the second plurality of rows comprising:
a plurality of lead frames, each lead frame of the plurality of lead frames comprising:
a die paddle;
a plurality of leads extending along the first direction; and
a plurality of tie bars connecting to the die paddle, the plurality of tie bars extending along the second direction;
mounting a plurality of transistors;
attaching a plurality of metal clips or a plurality of bond wires;
forming a molding encapsulation enclosing the plurality of transistors and the plurality of metal clips or the plurality of bond wires;
applying a punching process;
applying a sawing process separating the semiconductor package from adjacent semiconductor packages.

8. The method of claim 7, wherein the first plurality of rows and the second plurality of rows are symmetric with respect to the molding bus.

9. The method of claim 7 further comprising a plurality of sawing marks extending along the first direction.

10. The method of claim 7 further comprising a plurality of punching marks extending along the second direction.

11. The method of claim 7, wherein the plurality of leads comprises:
one or more upper leads connected to the die paddle; and
one or more lower leads separated from the die paddle;
wherein the one or more upper leads and the one or more lower leads are symmetric with respective to a center of the die paddle.

12. The method of claim 7, wherein the plurality of tie bars comprises:
a first tie bar; and
a second tie bar;
wherein the first tie bar and the second tie bar are symmetric with respective to a center of the die paddle.

13. The method of claim 7, wherein a top of the semiconductor package comprises:
a first straight edge extending along the first direction;
a second straight edge extending along the first direction, the second straight edge being opposite the first straight edge;
a first filleted edge extending along the second direction; and
a second filleted edge extending along the second direction, the second filleted edge being opposite the first filleted edge.

14. The method of claim 13, wherein a respective rectangular prism portion of each lead of the plurality of leads is exposed from the molding encapsulation.

15. The method of claim 13, wherein the molding encapsulation encloses a respectively shortened portion of each tie bar of the plurality of tie bars except that a respective sawed surface of each tie bar of the plurality of tie bars is exposed form the molding encapsulation.

16. The method of claim 7, wherein during the step of applying the punching process, a respective portion of each lead of the plurality of leads are removed.

17. The method of claim 7, wherein each lead frame of the plurality of lead frames comprises:
a plurality of metal sections between the plurality of leads; and
wherein during the step of applying the punching process, the plurality of metal sections and a respective portion of each lead of the plurality of leads are removed.
